(19) United States
(12) Patent Application Publication
(10) Pub. No.: US 2011/0151209 A1
(43) Pub. Date: Jun. 23, 2011

(54) SHELL FOR ELECTRONIC DEVICE, METHOD OF FORMING THE SHELL AND ELECTRONIC DEVICE HAVING THE SAME

(76) Inventors: Huating Li, Shenzhen (CN); Mintao Chen, Shenzhen (CN); Lei Zhong, Shenzhen (CN); Jiaxin Zhang, Shenzhen (CN)

(21) Appl. No.: 13/060,333

(22) PCT Filed: Aug. 28, 2009
(86) PCT No.: PCT/CN09/73626

§ 371 Date: Feb. 23, 2011

(30) Foreign Application Priority Data
Aug. 28, 2008 (CN) 200810146432.8

(51) Int. Cl. H05K 5/00; B32B 7/02; B32B 3/10; B32B 15/08; C23C 14/34; C23C 14/14; C25D 7/00; C25D 5/00; C23C 14/35; B05D 5/12; C23C 16/06; C23C 16/448

(52) U.S. Cl. 428/203; 428/209; 204/192.1; 205/205; 204/192.26; 427/58; 427/123; 427/124

(57) ABSTRACT

A shell for an electronic device is provided. The shell includes a transparent shell body, a pattern layer formed on an inner surface of the shell body, and a metal coating formed on an outer surface of the shell body which is light transmitting.

### CROSS REFERENCES TO RELATED APPLICATIONS

The present application claims priority to, and benefit of Chinese patent application No. 200810146432.8, filed on Aug. 28, 2008, the entirety of which is hereby incorporated by reference.

### FIELD OF THE INVENTION

The present invention relates to a shell for an electronic device, a method of forming the same and electronic device comprising the same.

### BACKGROUND

Electronic device shell are usually be decorated by printing patterns or forming relief. However, along with the improvement of the living standards, the individualized demands on electronic device become a main factor besides function and quality thereof. Therefore, it is urgent to develop a new shell for electronic device to satisfy the individualized demands of consumers.

### SUMMARY OF THE INVENTION

In viewing thereof, the present invention is directed to solve at least one of the problems existing in the prior art. Accordingly, a shell for an electronic device is needed to meet individualization requirement of consumers. And a method of forming the shell thereof and an electronic device comprising the same are also needed for individualization purpose.

According to an aspect of the invention, a shell for an electronic device is provided, comprising: a transparent shell body, a pattern layer formed on an inner surface of the shell body and a metal coating 3 formed on an outer surface of the shell body which is light transmitting.

According to another aspect of the invention, a method of forming a shell for an electronic device is provided, comprising the following steps: a shell body is provided. A pattern layer is formed on an inner surface of the shell body. A metal coating is formed which is light transmitting on an outer surface of the shell body.

According to yet another aspect of the invention, an electronic device is provided, comprising a body and a shell as described above configured to be mated with the body.

The metal coating on the outer surface overlaps with the patterns formed on the inner surface to provide favorable decorated effects on the shell thereof. When viewed from a point, the shell of electronic device has an effect of mirror. Whereas viewed from other point, the patterns on the shell of electronic device may be presented in a gleaming manner. Thus, the visual effect of the electronic device is enhanced greatly with improved individualization customization.

Additional aspects and advantages of the embodiments of present invention will be given in part in the following descriptions, become apparent in part from the following descriptions, or be learned from the practice of the embodiments present invention.

### BRIEF DESCRIPTION OF THE FIGURES

These and other aspects and advantages of the invention will become apparent and more readily appreciated from the following descriptions taken in conjunction with the drawings in which:

FIG. 1 is a longitudinal sectional view of a shell for an electronic device according to a first embodiment of the invention;

FIG. 2 is a longitudinal sectional view of a shell for an electronic device according to a second embodiment of the invention;

FIG. 3 is a longitudinal sectional view of a shell for an electronic device according to a third embodiment of the invention; and

FIG. 4 is a longitudinal sectional view of a shell for an electronic device according to a fourth embodiment of the invention.

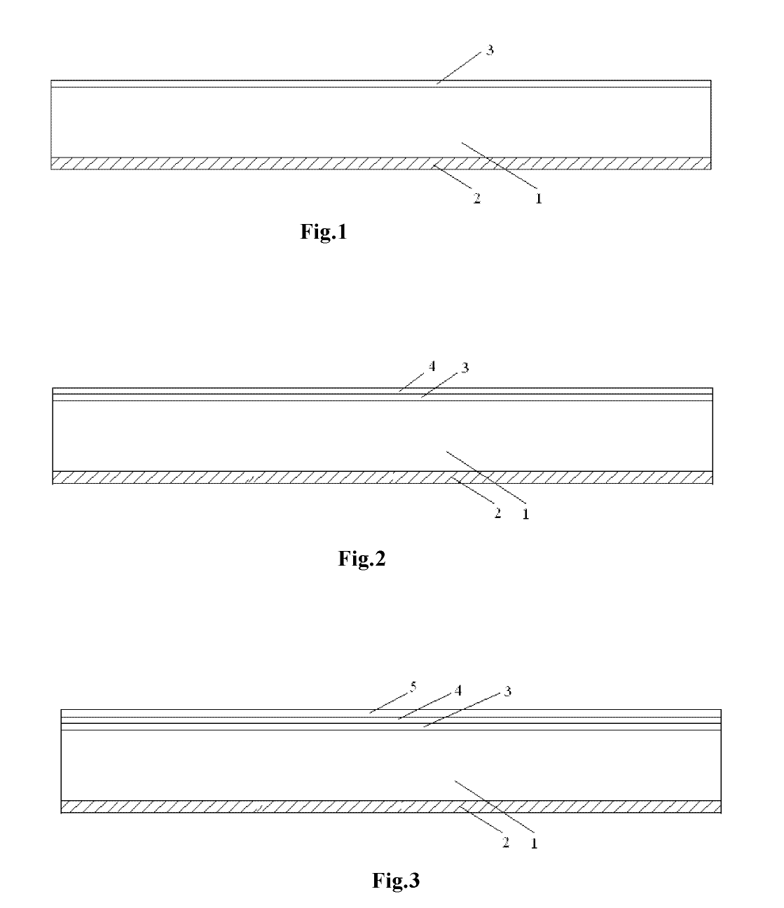

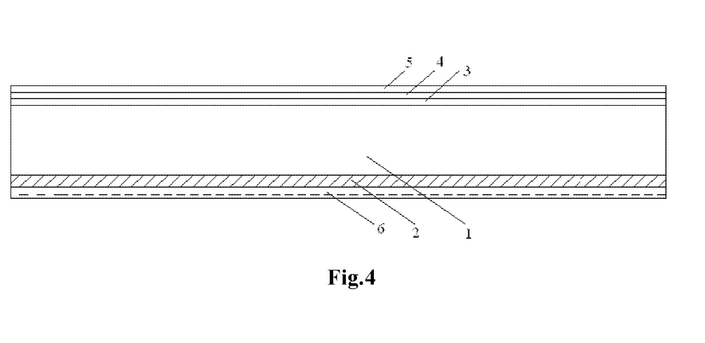

Reference characters used in the figures are as follows:
1—shell body;
2—pattern layer;
3—metal coating;
4—colored paint layer;
5—transparent protective layer;
6—protective layer.

### DETAILED DESCRIPTION OF THE INVENTION

According to one embodiment of the present invention, a shell for an electronic device is provided. The shell comprises a transparent shell body 1, a pattern layer 2 on an inner surface of the shell body 1 and a metal coating 3 which is light transmitting on an outer surface of the shell body 1.

In the present invention, the material and thickness of the metal coating 3 can be varied in a large range if only the electronic device shell has mirror surface effect and there is no effect on the patterns on the inner surface of the transparent shell. According to an embodiment of the invention, the thickness and the material of the metal coating 3 make the transmittance of the shell body 1 with the metal coating 3 being about 5-35%. The material of the metal coating 3 can be at least one of the Sn, Al, Ni, Cr, Cu, Ag and Ti.

The material of the shell body 1 can be any kind of transparent material which can be used to make shell for electronic device, such as one or two material selected from polycarbonate (PC) with weight average molecular weight of 20,000-60,000 and polymethyl methacrylate (PMMA) with weight average molecular weight of 20,000-200,000. The transmittance of the shell body 1 can be varied in a large range, for example, about 40-95%.

In order to improve the adhesion between the metal coating 3 and the shell body 1, there is a transparent primer layer on the outer surface of the shell body 1. The transparent primer layer lies between the shell body 1 and the metal coating 3. Moreover when there are blemishes on the outer surface of the shell body 1, the blemishes can be covered by the primer layer. Then the appearance of the electronic device shell is ameliorated.

The thickness of the transparent primer layer can be varied in a large range if only the adhesion of the metal coating 3 is enough. According to an embodiment of the invention, the thickness of the transparent primer layer is about 10-30 μm. The transmittance of the transparent primer layer can be varied in a large range. According to an embodiment of the invention, the transmittance of the transparent primer layer is about 85-95%. There is no limitation to the material of the transparent primer layer if only the function of the transparent primer layer is achieved, such as a UV gloss paint manufactured and distributed by Gaoyu Chemical material Co. Shenzheng, China.

The patterns can be changed in wide scope, such as one or more kinds selected from grapheme, sign and figure. The patterns can be one or two kinds selected from planar patterns and three-dimensional patterns.

In the present invention, there can be a colored paint layer 4 which is light transmitting formed on the surface of the metal coating 3. The color of the colored paint layer 4 can be varied in a large range, such as one or more color selected from red, orange, yellow, green, blue, indigo and purple. The thickness of the colored paint layer 4 can be varied in a large range if only the metal coating 3 has required color and there is no effect on appearing the patterns on the inner surface of the shell body 1, such as the thickness of the colored paint layer 4 is about 2-10 μm. The material of the colored paint layer 4 can be commercially obtained. And the colored paint layer 4 may be prepared by mixing the transparent colorless paint with a transparent pigment. And the added amount of the transparent pigment is about 1-5% (wt) of the total weight of the colored paint. The colored paint layer 4 can bring different color for electronic device shell in order to satisfy the individualized demands of consumers.

In the present invention, there is a transparent protective layer 5 formed on the surface of the colored paint layer 4 or metal coating 3 of the electronic device in order to protect the colored paint layer 4 or the metal coating 3. There is no limitation to the material of the transparent protective layer 5 if only the function of the metal coating 3 can be ensured and there is no effect on displaying the patterns, such as transparent coating with transmittance of 95%. According to an embodiment of the invention, the transmittance of the transparent protective layer 5 is about 85-95%. The thickness of the transparent protective layer 5 can be varied in a large range. According to an embodiment of the invention, the thickness of the transparent protective layer 5 is about 5-15 μm.

According to an embodiment of the invention, in order to protect the patterns on the inner surface of the shell body 1, there is a protective layer 6 on the inner surface of the shell body 1 so that the pattern layer can be positioned between the protective layer 6 and the inner surface of the shell body 1. The thickness of the protective layer 6 can be varied in a large range. For example, the thickness of the protective layer 6 can be about 5-20 μm. The material of the protective layer 6 can be commercially obtained, such as UV-curing paint with Model UV710 manufactured by Wuzang paint Ltd., Zhongshan, Guangdong Province, China.

According to another embodiment of the present invention, a method for forming the electronic device shell is provided. The method comprises the following steps: A shell body 1 is provided. A pattern layer 2 is formed on an inner surface of the shell body 1. A metal coating 3 which is light transmitting is formed on an outer surface of the shell body 1.

In the present invention, the method for forming metal coating 3 on the outer surface of the shell body 1 is optional, such as electroplating method, electroless plating method or physical vapor deposition method. According to an embodiment of the invention, the physical vapor deposition method is utilized. The physical vapor deposition method can be one or more deposition method selected from evaporating deposition and/or sputtering deposition. The sputtering deposition is further preferable because the adhesion between the shell body 1 and the metal coating 3 prepared by sputtering deposition is ameliorated and the thickness of the metal coating 3 is more uniform. The sputtering deposition step comprises the following step: electrifying the magnetron target so that the target material can be sputtered and deposited on the outer surface of shell body 1 under sputtering conditions.

The conditions of sputtering deposition can be those normally used in the art. With the magnetron sputtering as an example, the sputtering conditions comprises that in sputtering conditions, the power is applied on magnetron target. Then the target material is sputtered and deposited on the outer surface of the shell body 1. The target material can be selected from at least one of Sn, Al, Ni, Cr, Cu, Ag and Ti. The sputtering conditions can be changed in a wide scope. According to an embodiment of the invention, the transmittance of the shell body coated with metal coating 3 is about 5-35%, the sputtering pressure is about 2-5×10⁻¹ Pa, the sputtering power is about 2-4 KW, the sputtering time is about 2-4 seconds, and the sputtering process is performed by one or two times.

Every kind of existing magnetron sputtering coating machines can be used in the magnetron sputtering method in the present invention. The machines can be commercially purchased. The structure of the magnetron target is widely known in the art. For example, the magnetron target can include a target seat and a target material mounted on the target seat. The target seat is a magnet, and the magnet can be any kind of the prior magnets, such as one or more magnets selected from ferromagnet and Nd—Fe—B magnet.

The targets include single element target (a target contains one kind of target material) and multielement target (a target contains kinds of target material). According to an embodiment of the invention, the single element target is utilized. According to an embodiment of the invention, the purity of the target material is about more than 99.9%. The target material can be one or more material selected from Sn, Al, Ni, Cr, Cu, Ag and Ti.

The sputtering process is done in inert gas atmosphere. The inert gas does not participate in the sputtering reaction, such as N₂ and/or Ar. The amount of the inert gas is widely known in the art, such as the amount of the inert gas which can make the sputtering pressure reach 1-8×10⁻¹ Pa. The magnetron sputtering coating machine is vacuumized first so that the absolute pressure in the magnetron sputtering coating machine may reach 2×10⁻³ Pa to 5×10⁻³ Pa. Then the inert gas is injected so that the absolute pressure in the magnetron sputtering coating machine may reach 1-8×10⁻¹ Pa.

In the present invention, before the metal coating 3 is formed on the outer surface of the shell body 1, a transparent primer layer is formed on the outer surface of the shell body 1 so that the adhesion of the metal coating 3 may be improved, and the blemishes on the outer surface of the shell body 1 can be covered up. The method for forming the transparent primer layer on the outer surface of the shell body 1 is optional, such as, forming transparent primer layer on the outer surface of the shell body 1 by spraying. The spraying conditions make the thickness of the transparent primer layer is about 10-30 μm, the material of the transparent primer layer is the same as the material the above.

In the present invention, there is no limitation about forming the patterns on the inner surface of shell body 1, the methods such as one or more method selected from letterpress, gravure printing, lithographic printing, screen printing and thermal transfer printing. According to an embodiment of the invention, the thermal transfer printing is selected. The thermal transfer printing machine can be commercially purchased. The conditions of the thermal transfer printing machine can be varied in a wide scope, such as the temperature of the transfer printing part is about 160-300° C., the pressure of the transfer printing is about 60-120 Kgf, and the time of the transfer printing is about 0.5-2.5 seconds.

In order to improve the appearance effect of the shell for an electronic device, a colored paint layer 4 can be set on the surface of the metal coating 3. The color of the colored paint layer 4 can be varied in a large range, such as one or more color selected from red, orange, yellow, green, blue, indigo and purple. The material of the colored paint layer 4 can be the same as the materials mentioned above.

In order to further improve the appearance effect of the shell for an electronic device, a transparent protective layer 5 can be set on the surface of the colored paint layer 4. The method for setting the transparent protective layer 5 is widely known in the art, such as spraying. The material of the transparent protective layer 5 is the same as the materials the above.

In addition, to better protect the patterns formed on the inner surface of the shell body 1, a protecting layer 6 is formed on the inner surface of the pattern. And the forming methods are well known in the art. For example, a sputtering method may be used. And the material may be the same as those mentioned above.

According to another embodiment of the present invention, an electronic device is provided, and the electronic device comprises a body and a shell configured to be mated with the body. The shell thereof is prepared according to the present invention.

The body comprises all kinds of elements in the electronic device shell which can realize the functions of the electronic device, and the sorts, combination and connection relation of the elements are widely known in this field, which is hereby omitted for clarity purpose.

There is no limitation to the electronic device in the present invention, such as a mobile phone, a MP3, a PDA, a notebook computer and a digital camera and so on. According to an embodiment of the invention, a mobile phone is used as the electronic device.

The present invention will be described in detail with the following embodiments.

### First Embodiment

A shell body is put on a net plate of a continuous magnetron sputtering coater machine and sent into the vacuum chamber. The size of the shell body is about 110 mm×40 mm×0.8 mm, the material of the shell body is polycarbonate with weight average molecular weight of about 40,000, the transmittance of the material is about 90%. Then the vacuum pump is open, after the vacuum degree of the vacuum chamber reached about 3×10⁻² Pa, the shell body is cleaned with oxygen radiofrequency. The cleaning time is about 20 seconds, and the power is about 800 W. When the vacuum degree of the vacuum chamber reached about 3×10⁻³ Pa, Ar is charged in order to increase the pressure of the vacuum chamber to about 4×10⁻¹ Pa. Then Sn is coated by magnetron sputtering in order to form a Sn coating on the outer surface of the shell body. The purity of the Sn is about 99.99%. The sputtering power is about 2,000 W. The sputtering time is about 4 seconds, and the sputtering is about 1 time. A visible spectrophotometer is used to measure the transmittance of the shell body with the Sn coating. The result of the transmittance is about 6%.

A thermal transfer printing process is performed on the inner surface of the shell body with thermal transfer printing machine. The temperature of the transfer printing part is about 270° C. The pressure of the transfer printing is about 90 Kgf. The time of the transfer printing is about 1.5 seconds. Then, the shell body is put about 50 cm away from an ultraviolet lamp of about 50 W to be irradiated for about 1 minute. And the electronic device shell A1 is prepared accordingly.

### Second Embodiment

A transparent shell body is put on a net plate of a continuous magnetron sputtering coater machine and sent into the vacuum chamber. The size of the shell body is about 110 mm×40 mm×0.8 mm. The material of the shell body is polymethyl methacrylate with weight average molecular weight of about 120,000. The transmittance of the material is about 88%. Then the vacuum pump is open, after the vacuum degree of the vacuum chamber reaches about 3×10⁻² Pa, the shell body is cleaned with oxygen radiofrequency, the cleaning time is about 20 seconds, and the power is about 800 W. When the vacuum degree of the vacuum chamber reaches about 3×10⁻³ Pa, Ar is charged in order to increase the pressure of the vacuum chamber to about 3×10⁻¹ Pa. Then Al is coated by magnetron sputtering in order to form an Al coating on the outer surface of the shell body. The purity of the Al is about 99.99%, the sputtering power is about 2,500 W, the sputtering time is about 3 seconds, and the sputtering is performed by one time. A visible spectrophotometer is used to measure the transmittance of the shell body with Al coating, the result of the transmittance is about 30%.

Red transparent coating is sprayed on the Al coating to form a colored paint layer with a thickness of about 5 μm. The red transparent coating is prepared by mixing a transparent colorless paint with a transparent red pigment. The transmittance of the red transparent coating is about 45%. The amount of the transparent red pigment is about 2.5% (wt) of the total weight of the red transparent coating.

A thermal transfer printing process is performed on the inner surface of the shell body with a thermal transfer printing machine. The temperature of the transfer printing part is about 180° C. The pressure of the transfer printing is about 100 Kgf. The time of the transfer printing is about 2 seconds. The shell body is put about 50 cm away from an about 50 W ultraviolet lamp to be irradiated for about 1 minute, thus the electronic device shell A2 is prepared.

### Third Embodiment

A transparent shell body is put on the net plate of a continuous magnetron sputtering coater machine and sent into the vacuum chamber. The size of the shell body is about 110 mm×40 mm×0.8 mm. The material of the shell body is polymethyl methacrylate with weight average molecular weight of about 150,000. The transmittance of the material is about 95%. Then the vacuum pump is open, after the vacuum degree of the vacuum chamber reached about 3×10⁻² Pa, the shell body is cleaned with oxygen radiofrequency, the cleaning time is about 20 seconds, and the power is about 800 W. When the vacuum degree of the vacuum chamber reached about 3×10⁻³ Pa, Ar is charged in order to increase the pressure of the vacuum chamber to about 1.5×10⁻¹ Pa. Then Cu is coated by magnetron sputtering in order to form a Cu coating on the outer surface of the shell body. The purity of the Cu is about 99.99%, the sputtering power is about 3,000 W, the sputtering time is about 2.5 seconds, and the sputtering is performed by one time. The transmittance of the shell body with the Cu coating is about 10% tested by visible spectrophotometer.

Blue color paint is sprayed on the Cu coating to form a colored paint layer with a thickness of about 8 μm. The blue color paint is prepared by mixing transparent colorless paint with transparent blue pigment. The transmittance of the blue color paint is about 50% The amount of the transparent blue pigment is about 2.5% (wt) of the total weight of the blue color paint.

A thermal transfer printing process is performed on the inner surface of the shell body with thermal transfer printing machine. The temperature of the transfer printing part is about 295° C. The pressure of the transfer printing is about 75 Kgf, the time of the transfer printing is about 1 second. Then the shell body is put about 50 cm away from an about 50 W ultraviolet lamp to be irradiated for about 1 minute.

A transparent coating is sprayed on the blue color paint layer to form a protective layer with a thickness of 10 μm. The transmittance of the transparent coating is about 95%. Then the electronic device shell A3 is prepared.

### Fourth Embodiment

A transparent shell body is put on a net plate of a continuous magnetron sputtering coater machine and sent into the vacuum chamber. The size of the shell body is about 110 mm×40 mm×0.8 mm. The material of the shell body is polycarbonate with a weight average molecular weight of about 25,000. The transmittance of the material is about 70%. Then the vacuum pump is open. After the vacuum degree of the vacuum chamber reaches about 3×10⁻² Pa, the shell body is cleaned with oxygen radiofrequency, the cleaning time is about 20 seconds, and the power is about 800 W. When the vacuum degree of the vacuum chamber reaches about 3×10⁻³ Pa, Ar is charged in order to increase the pressure of the vacuum chamber to about 3×10⁻¹ Pa. Then Cr is coated by magnetron sputtering in order to form a Cr coating on the outer surface of the shell body. The purity of the Cr is about 99.99%, the sputtering power is about 3,500 W, the sputtering time is about 2 seconds, and the sputtering is performed by one time. The transmittance of the shell body with the Cr coating is about 15% tested by visible spectrophotometer.

A blue color paint is spraying on the Cr coating to form a colored paint layer with a thickness of about 4 μm. The blue color paint is prepared by mixing a transparent colorless paint with a transparent blue pigment. The transmittance of the blue color paint is about 50%. The amount of the transparent blue pigment is about 2.5% (wt) of the total weight of the blue color paint.

A thermal transfer printing process is performed on an inner surface of the shell body with a thermal transfer printing machine. The temperature of the transfer printing part is about 220° C., the pressure of the transfer printing is about 100 Kgf, the time of the transfer printing is about 2 seconds. Then the shell body is put about 50 cm away from an about 50 W ultraviolet lamp to be irradiated for about 1 minute.

A transparent coating is sprayed on the blue color paint layer to form a protective layer with thickness of about 15 μm. The transmittance of the transparent coating is about 95%.

A UV-curing coating is sprayed on the patterns on the inner surface of the shell body to form a protective layer with thickness of about 15 μm. Then, the electronic device shell A4 is prepared.

### Fifth to Eighth Embodiments

The electronic device shells A1-A4 prepared according to the first to fourth embodiments are tested as follows, the test results are shown in table 1.

Anti-Scratching Testing

A pencil (UNI) with a hardness of 2H is used to apply about 800 gf on the samples according to an orientation of about 45°, the travel distance is about 10 mm and every sample shall be scratched for 3 times. If there is no obvious scratch on the sample, the sample is qualified.

High-Temperature Resistance Testing

The samples are put into a precise high-temperature test chamber at about 85° C. for about 240 hours. Then the samples are put under room temperature for about 2 hours. If there is no shedding, distortion, flaw or color change on the sample, the sample is qualified.

Low Temperature Resistance Testing

The samples are put into a constant temperature and constant humidity box at about −40° C. for about 240 hours. Then the samples are put under room temperature for about 2 hours. If there is no shedding, distortion, flaw or color change on the sample, the sample is qualified.

Moisture Resistance Testing

The samples are put into a constant temperature and constant humidity box at about 60° C. for about 240 hours when the humidity is about 90%. Then, the samples are put under room temperature fore about 2 hours. If there is no shedding, distortion, flaw or color change on the sample, the sample is qualified.

Temperature Shock Testing

The samples are put into a cold and hot shock machine under about −40° C. for about 1 hour. Then the temperature is changed to about 85° C. and maintains for about an hour, the changing time is about 15 seconds. The samples suffers the cycle for 12 times (24 hours). If there is no shedding, distortion, flaw or color change on the sample, the sample is qualified.

Salt Spray Testing

The samples are put into a salt spray chamber at about 30° C. when the humidity is no less than about 85%. Then the samples suffers spraying with a solution whose PH value is about 6.8 (50 g/L NaCl solution) for about 48 hours before taken out. The samples are washed with clean water for about 5 minutes under room temperature, then the sample are dried with blower and put under room temperature for about 1 hour. If there is no shedding, distortion, flaw or color change on the sample, the sample is qualified.

Hundred Grids Testing

The samples are put on a flat and hard table. A cross-open cutting machine is used to form grids on the surface of the samples. The grids are formed by cutting a plurality of linear traces which are crossed with each other by an angle of 90 is degrees. The traces should be deep enough to reveal the substrates of the samples. After the hundred grids area is adhered with adhesive tape for about 5 minutes, the adhesive tape is pulled away by an angle of 60° in about 0.5-1 second. Then the samples are observed under microscope to confirm if the traces are smooth and if the coatings fell off. The percentage of the grids falling off in total grids is calculated.

Drop Ball Impact Testing

According to the GB/T 1732 and ASTMD2794-93 testing standards, the samples are put on a testing table of the drop ball tester. The mass of a dropping ball is about 170 g with a drop height being about 60 cm. After the drop ball impacts the samples for 10 times, the samples on which there is no shedding, distortion or flaw are qualified.

Tumbling-Dropping Testing

The samples are put into a sample clamp of a tumbling-dropping tester and dropped with tumbling. The drop height is about 500 mm. The drop frequency is about 5 times per minute. The drop degree is about 20 times. The samples on which there is no shedding, distortion or flaw are qualified.

TABLE 1

| | Embodiment No. | | | |
|---|---|---|---|---|
| | Embodi- | Embodi- | Embodi- | Embodi- |
| | ment 5 | ment 6 | ment 7 | ment 8 |
| Sample No. | A1 | A2 | A3 | A4 |
| Anti-scratching testing | Qualified | Qualified | Qualified | Qualified |
| High-temperature | Qualified | Qualified | Qualified | Qualified |
| resistance testing | | | | |
| Low temperature | Qualified | Qualified | Qualified | Qualified |
| resistance testing | | | | |
| Moisture resistance | Qualified | Qualified | Qualified | Qualified |
| testing | | | | |
| Temperature shock | Qualified | Qualified | Qualified | Qualified |
| testing | | | | |
| Salt spray testing | Qualified | Qualified | Qualified | Qualified |
| Hundred grids testing | 2% | 2% | 1% | 1% |
| Drop ball impact testing | Qualified | Qualified | Qualified | Qualified |
| Tumbling-dropping | Qualified | Qualified | Qualified | Qualified |
| testing | | | | |

As shown in the table 1, the properties of the shell for electronic device according to the present invention can meet the qualification. The metal coating 3 on the outer surface of the shell body 1 matches the patterns on the inner surface of the shell body 1 very well so that the electronic device shell has attractive and ameliorated design effects to satisfy the individualized customization of different kinds of consumers.

Although explanatory embodiments have been shown and described, it would be appreciated by those skilled in the art that changes, alternatives, and modifications can be made in the embodiments without departing from spirit and principles of the invention. Such changes, alternatives, and modifications all fall into the scope of the claims and their equivalents.

1. A shell for an electronic device, comprising:
a transparent shell body;
a pattern layer formed on an inner surface of the shell body; and
a metal coating formed on an outer surface of the shell body which is light transmitting.

2. The shell according to claim 1, wherein the metal coating of the shell body has a transmittance of about 5-35%.

3. The shell according to claim 1, wherein the shell body has a transmittance of about 40-95%.

4. The shell according to claim 1, wherein the shell further comprises a colored paint layer on the metal coating which is light transmitting.

5. The shell according to claim 4, wherein the shell further comprises a transparent protective layer formed on a surface of the colored paint layer.

6. The shell according to claim 1, wherein the shell further comprises a protective layer on the inner surface of the shell body with the pattern layer interposing between the protective layer and the inner surface of the shell body.

7. A method of forming a shell for an electronic device, comprising:
providing a shell body;
forming a pattern layer on an inner surface of the shell body; and
forming a metal coating which is light transmitting on an outer surface of the shell body.

8. The method according to claim 7, wherein the metal coating is formed on the outer surface of the shell body by electroplating, electroless plating or physical vapor depositing.

9. The method according to claim 8, wherein the physical vapor deposition is evaporating deposition and/or sputtering deposition.

10. The method according to claim 9, wherein the physical vapor deposition is sputtering deposition.

11. An electronic device comprising a body and a shell according to claim 1 which is configured to be mated with the body.

12. The shell according to claim 1, wherein material of the metal coating is selected from one or more of Sn, AI, Ni, Cr, Cu, Ag and Ti.

13. The shell according to claim 1, wherein the shell body is made of polycarbonate with weight average molecular weight of about 20,000-60,000 and/or polymethyl methacrylate with weight average molecular weight of about 20,000-200,000.

14. The shell according to claim 4, wherein the colored paint layer has a color selected from one or more of red, orange, yellow, green, blue, indigo and purple.

15. The shell according to claim 4, wherein the colored paint layer has a thickness of about 2-10 μm.

16. The shell according to claim 5, wherein the protective layer has a transmittance of about 85-95%.

17. The shell according to claim 5, wherein the protective layer has a thickness of about 2-20 μm.

18. The shell according to claim 6, wherein the protective layer has a thickness of about 5-20 μm.

19. The method according to claim 10, wherein the sputtering deposition comprises the following step:
electrifying a magnetron target so that a target material can be sputtered and deposited on the outer surface of the transparent shell body under sputtering conditions.

20. The method according to claim 19, wherein the target material is selected from at least one of Sn, AI, Ni, Cr, Cu, Ag and Ti, resulting in a shell body with metal coating which is light transmitting having a transmittance of 5-35%.
